(19) United States
(12) Patent Application Publication
(10) Pub. No.: US 2025/0093422 A1
(43) Pub. Date: Mar. 20, 2025

(54) A METHOD FOR QUALITY TESTING OF A BATTERY AND A BATTERY FORMATION SYSTEM

(71) Applicant: Accure Battery Intelligence GmbH, Aachen (DE)

(72) Inventors: Kai-Philipp KAIRIES, Aachen (DE); Georg ANGENENDT, Aachen (DE); Matthias KUIPERS, Aachen (DE)

(73) Assignee: Accure Battery Intelligence GmbH, Aachen (DE)

(21) Appl. No.: 18/729,552

(22) PCT Filed: Feb. 10, 2022
(86) PCT No.: PCT/EP2022/053241

§ 371 Date: Jul. 17, 2024

(51) Int. Cl. G01R 31/385; G01R 31/367; H01M 10/42; H01M 10/44; H01M 10/48

(52) U.S. Cl. CPC G01R 31/3865; G01R 31/367; H01M 10/4285; H01M 10/44; H01M 10/48

(57) ABSTRACT

A method (S200) for quality testing of a battery is disclosed. The method (S200) comprising performing (S210) a battery formation process on the battery: acquiring (S220) data of the battery from the battery formation process, and the data of the battery temporally relates electrical characteristics of the battery; and quality testing (S230) of the battery by phase-wise comparing and/or cycle-wise comparing the acquired data with reference battery data, and a phase is one of: a charge phase, a transitional phase and a discharge phase of the battery formation process, and a cycle comprises consecutive phases of the charge phase, the transitional phase and the discharge phase.

### TECHNICAL FIELD

The invention relates to concepts for quality testing of a battery and applications thereof and in particular to a method for quality testing of a battery and a battery formation system.

The following background is intended solely to provide information necessary to understand the context of the inventive ideas and concepts disclosed herein. Thus, this background section may contain patentable subject-matter and should not be regarded as a disclosure of prior art.

### BACKGROUND

During manufacturing, battery cells go through three main processes: Mechanical production, formation, and end-of-line (EOL) testing.

The mechanical production includes the Electrode manufacturing, the cell assembly, and the cell finishing. The formation is the process of initially charging and discharging a newly produced battery cell.

The formation is conducted using specialized test equipment (herein also referred to as battery formation system) and can take a few hours but also multiple days of time. During the formation, voltage, current and temperature of the battery cell are measured by the test equipment. In manufacturing rechargeable batteries, for example electrical vehicle (EV) batteries, the formation process (which is also called battery formation or cell formation herein) is to transform the components of a new cell, in particular the active materials, the interphases between active materials and the electrolyte as well as the distribution of the electrolyte, into their usable form. Charge and discharge cycles are applied to the battery cell in order to activate the material in a newly built battery cell and have an enormous impact on life, quality and cost of a battery cell and are therefore indispensable. During charging and discharging, battery cells are normally monitored and controlled due to a high energy density involved in the process. Existing battery formation systems typically have integrated voltage sensing, temperature sensing and safety control electronics. Moreover, battery cells are typically assembled in fixtures, holding multiple cells at the same time, which are going through the formation process simultaneously.

EOL testing of the battery cells is the final process in battery manufacturing. A large percentage (up to 100%) of the battery cells are tested for their properties in order to rate the quality (e.g. very good, good or fail) and to match similar battery cells' characteristics when provided in batches. Reducing an amount of EOL testing can substantially reduce the cost of battery manufacturing and is therefore favourable. Getting a more detailed evaluation of the quality of battery cells allows for process optimization and market differentiation and is therefore also favourable.

Altogether, all three steps of manufacturing are time consuming. Thus, there may be a demand to provide concepts for reducing manufacturing time. In addition, the manufacturing costs should be reduced.

### SUMMARY

Such a demand may be satisfied by the subject-matter of the independent claims.

This summary is provided to introduce a selection of features and concepts of embodiments of the present invention that are further described below in the detailed description. This summary is not intended to identify key or essential features of the claimed subject-matter, nor is it intended to be used in limiting the scope of the claimed subject-matter. One or more of the described features may be combined with one or more other described features to provide a workable method or device.

Specifically, such a demand may be satisfied by a method for quality testing of a battery. The method comprises performing a battery formation process on the battery. The method further comprises acquiring data of the battery from the battery formation process, and the data of the battery temporally relates electrical characteristics of the battery. The method comprises quality testing of the battery by phase-wise comparing the acquired data with reference battery data. In addition, or in an alternative thereto, the method comprises the quality testing of the battery by cycle-wise comparing the acquired data with the reference battery data. A phase is or includes one of: a charge phase, a transitional phase and a discharge phase of the battery formation process. A cycle comprises or consists of consecutive phases of the charge phase, the transitional phase and the discharge phase.

This has the advantage that a downstream process of EOL testing can be omitted or shortened in time. Thus, manufacturing costs can be reduced.

The electrical characteristics may at least include voltage and current. For example, the data of the battery temporally relates current through the battery with terminal voltage of the battery. So current and voltage may be timey resolved in the acquired data. It may be clear to a person skilled in the art that outliers in the raw data from the measured electrical characteristics may be omitted by a pre-processing step which could be performed during the acquiring step of on the acquired data, where the quality check is made on the pre-processed data.

The battery referred to herein may be a module, cell or pack, and more particularly a battery cell of a batch of a plurality of battery cells which undergo a same battery formation process at a same time.

The temporal relation of the electrical characteristics may be time-resolved. The phase-wise comparison may be a comparison that is performed per phase of the time-resolved acquired data and the cycle-wise comparison may be a comparison that is performed per cycle of the time-resolved acquired data. In particular, a cycle may include all the phases once.

Particularly advantageous configurations can be found in the dependent claims.

The method may follow a mechanical production process of the battery. A process of degassing may be considered part of the mechanical production process in case degassing is performed on the battery. In consequence, the method may be the direct process after the mechanical production process or in between the mechanical production process.

This enables a reduction of time in manufacturing the battery.

The method may further comprise refraining from performing an End-Of-Line Test process of the battery. The quality testing of the battery may be performed during the battery formation process, in particular instead of at least part of an End-Of-Line (EOL) Test process of the battery.

This may further reduce the manufacturing time of the battery.

The quality testing of the battery and/or the acquiring the data of the battery may be performed upon an initial state of the battery is detected. The initial state may be a state where the battery has not been activated yet, such as a state around approximately 0 Volt. Nevertheless, the initial state may also be a partly formatted state, where the battery is formatted but only partly, or the active materials have been selected accordingly or pre-treated during the manufacturing of the cell. This may also include, but may not be limited to, the technique of prelithiation or pre-doping of lithium ions which technique describes the addition of lithium to the active lithium content.

This may enhance the processing of the data acquisition and testing.

The battery formation process may further comprise steps of periodically charging the battery during the charge phase and discharging the battery during the discharge phase. The step of acquiring the data of the battery during the battery formation process may comprise acquiring the data stepwise according to the steps of periodically charging and discharging. The transitional phase may be between the charge phase and the discharge phase, the charge phase to another charge phase, or the discharge phase to another discharge phase. The transitional phase may be from the discharge phase to the charge phase, from the discharge phase to the other discharge phase, from the charge phase to the other charge phase, and/or from the charge phase to the discharge phase. The term “transitional phase” may be understood as a transition, where a flank, in particular a current flank, is steep in time resolution. The steepness may be larger than 0.01 (0.05, 0.1, 0.5, 1 or 10) A/s. However, it may be understood, that the transitional phase may be a monotonic function, but may also have a rest phase in between transitional phase, such as a plateau or rest phase, which may be shorter (in time) than a total of the transitional phase, or shorter than ⅓, ⅕, ⅛ or 1/10 of the overall transitional flank.

In consequence, the quality test may be performed on stepwise acquired data in order to decrease the manufacturing process time.

The reference battery data may be or may include data gathered from a historical battery data set of at least one battery batch. The at least one or more battery batch may be a different battery batch or multiple different battery batches as a battery batch the (current) battery belongs to. Further, the at least one battery batch may be a historic battery batch or multiply different historic battery batches. Further, the at least one battery batch. In an alternative or in addition, the reference battery data may be or may include data from a current battery data set of a same batch, the (current) battery belongs to.

Thus, data fusion may be applied to ensure a quality of the method.

The quality testing of the battery may be performed while the acquiring of the data of the battery is carried out. The quality testing of the battery may be performed on the data which accords to a fixed step in the battery formation process, during a subsequent step of the battery formation process.

This enables to use a specific section of data like a window to perform the method on a reduced amount of data. Thereby efficiency and latency can be reduced.

The method may further comprise extracting one or more functional profiles from the (stepwise) acquired data. The quality testing may further comprise comparing the one or more functional profiles of the acquired data and corresponding one or more functional profiles of the reference battery data.

Thus, a simple function-wise comparison may be enabled to reduce an effort of achieving a quality test.

The quality testing may further comprise triggering one or more indicators when respective one or more differences between the one or more functional profiles of the acquired data and the corresponding one or more functional profiles of the reference battery data exceed corresponding one or more predetermined thresholds. The one or more indicators may be a quality flag which may indicate that the battery is defect. To have a more reliable output, the more indicates may be used to indicate a defect in the battery. In this case, multiple thresholds may be exceeded which trigger the multiple indicators.

The indicators may be simple flag(s) as pointers to the battery, where one or more flag(s) such as more than three flags may indicate a failure. Thus, the battery may be omitted from the batch. Further, the threshold may be a nominal or normed value in a range between 0.05 and 0.3, or 0.1 and 0.2. In addition or in an alternative the indicators/flags may be used to indicate a future/target batch membership/affiliation. Thus, batteries of a same batch may be organized to different batches in accordance with the indicators/flags. For example, a number of indicators/flags may indicate a future/target batch to which the corresponding battery is assigned/allocated after the formation process. Thus, the battery is assigned/transferred to a target battery batch which includes batteries with similar/same indicators/flags. In consequence, the target battery batch includes batteries with similar characteristics, which increases an application performance and thus quality when in use.

The data or the functional profile may include derivatives of a charge of the battery with respect to a terminal voltage of the battery per the respective charge and discharge phases. The data or the functional profile may include derivatives of the terminal voltage of the battery with respect to the charge of the battery per the respective charge and discharge phases. The data or the functional profile may include charge and/or energy throughputs per the respective charge and discharge phases. The data or the functional profile may include internal resistances per the respective transitional phases, e.g., per the flanks at the end of the respective transitional phases. The data or the functional profile may include electrical circuit models per the respective transitional phases and/or the electrical circuit models per the respective discharge phases and/or charge phases. The data or the functional profile may include coulomb/energy/voltaic efficiencies per the respective cycles.

Consequently, a multiple categories diagnosis can be implemented as quality test during the battery formation process.

The quality testing may be performed by respectively comparing at least one maximum and/or at least one minimum of the derivatives against at least one maximum and/or at least one minimum of derivatives in the reference battery data, and/or respectively comparing the derivatives to corresponding statistical upper and lower boundary curves associated with the reference battery data.

The quality testing may be performed by respectively comparing the charge and/or energy throughputs against at least one first statistical boundary condition of the reference battery data;

The quality testing may be performed by comparing the internal resistances against at least one second statistical boundary condition of the reference battery data;

The quality testing may be performed by fitting parameters of the electrical circuit models to the data or the functional profile and respectively comparing the parameters of the electrical circuit models against corresponding parameters of an equivalent electrical circuit model of the reference battery data and/or respectively comparing the parameters against at least one third statistical boundary condition associated with the corresponding parameters of the reference battery data. One of the electrical circuit models may be a series connection, from one voltage terminal of the battery to the other voltage terminal of the battery, of a voltage source, a first resistor and a parallel connection of a second resistor and a capacitor. Another one of the electrical circuit models may be a series connection, from one voltage terminal of the battery to the other voltage terminal of the battery, a third resistor and a Warburg impedance. The parameters as described herein may be understood as values of the respective components of the used electrical circuit model. Thus, a proper Q factor can be ensured.

The quality testing may be performed by comparing the coulomb and/or energy and/or voltaic efficiencies against at least one fourth statistical boundary condition of the reference battery data.

The at least one first, second, third and fourth statistical boundary conditions may be independent from one another. For example, the at least one first, second, third and fourth statistical boundary conditions may be different from one another. The at least one first, second, third and fourth statistical boundary conditions may correspond to a respective envelope of a statistical distribution of values of the reference battery data, such as a normal distribution or Gaussian distribution. The at least one first, second, third and fourth statistical boundary conditions may be each a set of boundary conditions. The set of boundary conditions can be tested in a consecutive manner, for example depending on a previous boundary condition being met or not.

Consequently, data fusion of some or all of these schemes may ensure a better quality testing of the battery.

The above-mentioned demand is also solved by a computer program. The computer program product comprises instructions which, when the program is executed by a computer, cause the computer to carry out the steps of the method above.

The above-mentioned demand is also solved by a computer-readable data carrier. The computer-readable data carrier has stored there on the computer program above.

The above-mentioned demand is also solved by a battery formation system for quality testing of a battery. The battery formation system comprises a monitor/control unit. The monitor/control unit is configured to measure electrical characteristics of the battery and further configured to instruct a battery formation process on the battery. The battery formation system further comprises a processing unit. The processing unit is configured to acquire data of the battery based on the measured electrical characteristics during the battery formation process. The data of the battery temporally relates the measured electrical characteristics of the battery. The battery formation system is configured to quality test the battery by phase-wise comparing and/or cycle-wise comparing the acquired data with reference battery data. The phase is one of: a charge phase, a transitional phase and a discharge phase of the battery formation process. The cycle comprises consecutive phases of or consists of the charge phase, the transitional phase and the discharge phase.

This enables a reduction of time in manufacturing the battery and thus cost thereof.

In addition, the battery formation system may include a gateway for transmitting the acquired data to the processing unit. The processing unit may be part of an on-site or remote cloud system. Further, the battery formation system may be part of a synced battery formation system assembly which are in sync over air by use of the on-site or remote cloud system. Thus, a current batch or historic batches may be part of synchronized batches on remote battery factories around the world. Further, the battery formation system assembly may be desynced such that data acquired during a battery formation system at one of the battery formation systems of the battery formation system assembly can be used (as or) as part of the reference battery data for another battery formation system of the battery formation system assembly.

Moreover, the processing unit and the monitor/control unit may engage in a long-range communication, where a gateway is used between the monitor/control unit and the processing unit. The gateway and the monitor/control unit may engage in a short-range communication.

Further, the battery formation system may be a legacy battery formation system.

In other words, the invention concerns to bring the EOL testing process into the battery formation process.

Even if some of the aspects described above have been described in reference to the method, these aspects may also apply to battery formation system. Likewise, the aspects described above in relation to battery formation system may be applicable in a corresponding manner to the method.

It is clear to a person skilled in the art that the statements set forth herein under use of hardware circuits, software means or a combination thereof may be implemented. The software means can be related to programmed microprocessors or a general computer, an ASIC (Application Specific Integrated Circuit) and/or DSPs (Digital Signal Processors).

For example, the system and the devices and units included in the system may be implemented partially as a computer, a logical circuit, an FPGA (Field Programmable Gate Array), a processor (for example, a microprocessor, microcontroller (μC) or an array processor)/a core/a CPU (Central Processing Unit), an FPU (Floating Point Unit), NPU (Numeric Processing Unit), an ALU (Arithmetic Logical Unit), a Coprocessor (further microprocessor for supporting a main processor (CPU)), a GPGPU (General Purpose Computation on Graphics Processing Unit), a multi-core processor (for parallel computing, such as simultaneously performing arithmetic operations on multiple main processor(s) and/or graphical processor(s)) or a DSP.

It is further clear to the person skilled in the art that even if the herein-described details will be described in terms of a method, these details may also be implemented or realized in a suitable device, a computer processor or a memory connected to a processor, wherein the memory can be provided with one or more programs that perform the method, when executed by the processor. Therefore, methods like swapping and paging can be deployed.

It is also to be understood that the terms used herein are for purpose of describing individual embodiments and are not intended to be limiting. Unless otherwise defined, all technical and scientific terms used herein have the meaning which corresponds to the general understanding of the skilled person in the relevant technical field of the present disclosure; they are to be understood neither too far nor too narrow. If technical terms are used incorrectly in the present disclosure, and thus do not reflect the technical concept of the present disclosure, these should be replaced by technical terms which convey a correct understanding to the skilled person in the relevant technical field of the present disclosure. The general terms used herein are to be construed based on the definition in the lexicon or the context. A too narrow interpretation should be avoided.

It is further to be understood that the disclosure of multiple method steps disclosed in this description or the claims may not be construed as to be within a specific order, unless explicitly or implicitly stated otherwise, for instance for technical reasons. Therefore, the disclosure of multiple steps will not limit these to a particular order unless such steps are not interchangeable for technical reasons. Furthermore, in some examples a single step may include or may be broken into multiple sub-steps, respectively. Such sub steps may be included and part of the disclosure of this single step unless explicitly excluded. It is also to be understood that the steps as disclosed herein may be performed directly one after the other (consecutively, subsequently, sequentially), continuously and/or successively. Nevertheless, there may also be other steps in between. On the other hand, if a step is “directly subsequent/preceding” to another step or “directly after/before” the other step, it is to be assumed that there are no other step(s) in between.

### BRIEF DESCRIPTION OF THE DRAWINGS

In the following, the invention shall be explained in more detail by means of the embodiment(s) with reference to the attached schematic figures. The figures show:

FIG. 1 an illustration of a battery formation system for quality testing of a battery; and

FIG. 2 an illustration of a method for quality testing of a battery.

### DETAILED DESCRIPTION

The method S200 for quality testing and the battery formation system 1 will now be described with respect to the embodiments. In particular, without being restricted thereto, specific details are set forth to provide a thorough understanding of the present disclosure. However, it is clear to the skilled person that the present disclosure may be used in other embodiments, which may differ from the details set out below.

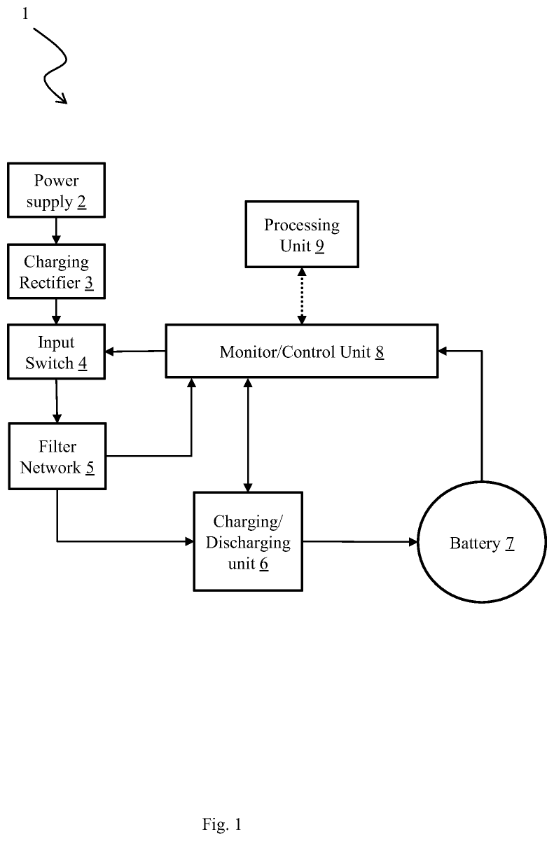

FIG. 1 shows a battery formation system 1 for quality testing of a battery 7. The battery formation system 1 includes a power supply 2, a charging rectifier 3, an input switch 4, a filter network 5, a charging/discharging unit 6 and a monitor/control unit 8. The battery formation system 1 can also include a processing unit 9 as an internal or external device to the monitor/control unit 8. The functionality of the processing unit 9 can be part of or fully part of the monitor/control unit or separate therefrom. The charging rectifier 3 can be an on-site system-integrated charging rectifier available at the manufacturing facility, or provided as integrated part of the battery formation system 1.

The power supply 2 can be one of DC or AC power supply. In case of a DC power supply 2, the charging rectifier 3 is not used in the battery formation system 1. In case of an AC power supply, the charging rectifier 3 is used downstream of the power supply 2 as part of the battery formation system 1. The power supply 2 and/or the charging rectifier 3 supplies direct current (DC) to the input switch 4. The input switch 4 is controlled by the monitor/control unit 8 in a stepwise manner according to the processing steps of the formation process. For example, a pulse-width modulation (PWM) is applied from the monitor/control unit 8 to the input switch 4 in accordance with respective charging and discharging cycles of the battery formation process. The switched current is supplied from the input switch 4 to the downstream filter network 5. For example, an isolated voltage sample is transmitted from the filter network 5 to the monitor/control unit 8. Thereafter, the current is supplied from the filter network 5 to the downstream charging/discharging unit 6. The monitor/control unit 8 also controls the charging/discharging unit 6. Further, an isolated current sample is transmitted from the charging/discharging unit 6 to the monitor/control unit 8. The current from the charging/discharging unit 6 is then supplied to the battery 7 or vice versa.

During the charging and discharging cycles, the monitor/control unit 8 measures the electrical characteristics of the battery 7. The battery 7 can be in many forms, for example, one or more batteries, or one or more cells, in separate or combined containers. The monitor/control unit 8 may use the samples of electrical characteristics, such as voltage, current and/or capacity samples, to control the charge/discharge process of the battery 7. More particular, the monitor/control unit 8 gathers and/or transmits the samples of electrical characteristics, such as voltage, current and/or capacity samples, directly to the processing unit 9 for further processing of the samples. The transmission of these samples can be in a batch-like manner, such that the samples are batch processed per charging and/or discharging cycle or per storage amount and then transmitted to the processing unit 9. Further, the transmission can take place directly after measuring the electrical characteristics in a continuous manner during the battery formation process.

The monitor/control unit 8 may be electrically and/or communicatively connected (singularly or in multiplicity) to the processing unit 9, which can be some kind of external monitor, command and data collection processor. The connection between the monitor/control unit 8 and the processing unit 9 can also be in the form of a wireless connection. Therefore, different standards such as ZigBee, WLand, Bluetooth, Dect or any other Long Range Communication or Dedicated Short Range Communication.

In particular, the charging rectifier 3 as a direct current (DC) power source can provide up to 600 V at current levels of 5 to 500 A on a continuous basis, and not be under current control. Depending on the application, voltage levels of the charging rectifier 10 may be varied to adaptively lower the input voltage to the battery 7 to reduce battery heating, and to reduce total power consumed during the charging and discharging cycles. The charging rectifier 10 can be a linear silicon controlled rectifier based DC power supply.

The input switch 4 controls the voltage provided to the filter network 5. The voltage on the filter network 5 can be monitored by an isolated voltage measurement device monitored by the monitor/control unit 8. The input switch 4 can replace a charging rectifier voltage control sub-system. The input switch 4 can also eliminate interfacing issues presented by a wide variety of rectifier manufacturers and control methodologies.

The filter network 5 can reduce or eliminate any line-frequency AC components from the power supply 2 and can supply a stable voltage that is largely independent of input power fluctuations. The filter network 5 can also provide an isolated voltage sample to the monitor/control unit 8.

The output voltage of the filter network 5 may be controlled by the charging/discharging unit 6 which can also be monitored by an isolated voltage measurement device as well as an isolated current measurement device, both of which may be monitored by the monitor/control unit 8. The charging/discharging unit 6 controls the current that is delivered to the battery 7. The charging/discharging unit 6 can be an insulated gate bipolar transistor (IGBT), which allows for quick and repetitive cycling to generate high energy charge pulses during the charging cycle of the battery formation process.

The monitor/control unit 8 can monitor at least one of the following: isolated voltage samples from the input switch 4, the filter network 5 and the battery 7; isolated current samples from the charging/discharging unit 6; and isolated temperature sensors (not shown) external to battery 7. These measurements can be used by the monitor/control unit 8 in various calculations to determine the amount of charge acceptance, the end of charge cycle, electrochemistry latency, battery internal resistance, and heat rise over ambient. These calculations can then be used by the monitor/control unit 8 to control both the input switch 4 and the charging/discharging unit 6 in such a manner as to perform an efficient charge of the battery 7 within a desired time. The monitor/control unit 8 can also provide this data to the processing unit 9. Moreover, the above-mentioned calculations can take place in the (separate) processing unit 9. It may also be understood that the processing unit 9 may be an integral part of the monitor/control unit 8 which provides various calculation steps and indications derived from these calculations. For example, the calculations may be specifically directed to quality tests based on the measured electrical characteristics such as current, voltage and capacity of the battery 7 during the battery formation process of the battery 7.

The monitor/control unit 8 can calculate the desired control levels for the input switch 4 and the charging/discharging unit 6. The monitor/control unit 8 can also calculate the desired charge frequency and energy while maintaining battery temperature in a desired range during the charge cycle. The monitor/control unit 8 can calculate charge cycle completion by a singular or a multitude of measured and calculated variables. The monitor/control unit 8 can also prevent operation at resonance frequencies, and detect a variety of charge cycle errors, including open circuits, loose connections, and run away currents.

The monitor/control unit 8 can include an output device, such as a display, and an input device, such as a keypad. In embodiments with an output device, the monitor/control unit 8 can provide real-time status and data on the output device. In embodiments with an input device, the monitor/control unit 8 can accept command data from the input device. The monitor/control unit 8 can also accept command data from the processing unit 9.

The processing unit 9 can provide facility-wide data collection, monitoring and control of one or a series of battery formation systems 1, and can provide data analysis tools for quality control measures and quality testing of the battery 7. The processing unit 9 can also provide real-time process optimization data, historical data for post-mortem failure analysis, and both real-time and historical data for engineering trials without interfering with manufacturing or production control.

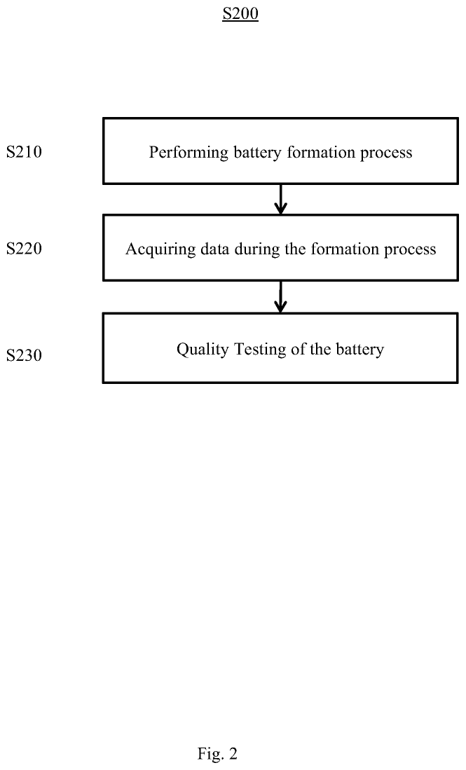

FIG. 2 shows a method S200 for quality testing of the battery 7 which follows the mechanical production process of the battery 7, the method S200 comprising performing S210 a battery formation process on the battery 7, acquiring S220 data of the battery 7 from the battery formation process, and the data of the battery temporally relates electrical characteristics of the battery 7, and quality testing S230 of the battery 7 by phase-wise comparing and/or cycle-wise comparing the acquired data with reference battery data, where a phase is one of a charge phase, a transitional phase and a discharge phase of the battery formation process, and a cycle is constructed by these phases.

The aspects and features mentioned and described together with one or more of the previously detailed examples and figures, may as well be combined with one or more of the other examples in order to replace a like feature of the other example or in order to additionally introduce the feature to the other example.

At this point it should be noted that all of the above-described parts are considered to be essential to the invention when viewed on their own and in any combination, especially the details shown in the figures. Modifications of this are familiar to the skilled person.

### LIST OF REFERENCE SIGNS

1 battery formation system
2 power supply
3 charging rectifier
4 input switch
5 filter network
6 charging/discharging unit
7 battery
8 monitor/control unit
9 processing unit

1. A method for quality testing of a battery,
the method comprising:
performing a battery formation process on the battery;
acquiring data of the battery from the battery formation process, wherein the data of the battery temporally relates electrical characteristics of the battery; and
quality testing of the battery by phase-wise comparing and/or cycle-wise comparing the acquired data with reference battery data, and a phase is one of: a charge phase, a transitional phase and a discharge phase of the battery formation process, and a cycle comprises consecutive phases of the charge phase, the transitional phase and the discharge phase.

2. The method according to claim 1, wherein
the method follows a mechanical production process of the battery.

3. The method according to claim 1, wherein
the method further comprises refraining from performing an End-Of-Line Test process of the battery; and/or
the quality testing of the battery is performed during the battery formation process.

4. The method according to claim 1, wherein
the quality testing of the battery and/or the acquiring the data of the battery is performed upon an initial state of the battery is detected.

5. The method according to claim 1, wherein
the battery formation process further comprises steps of periodically charging the battery during the charge phase and discharging the battery during the discharge phase, that the acquiring the data of the battery during the battery formation process comprises acquiring the data stepwise according to the steps of periodically charging and discharging, and that the transitional phase is between the charge phase and the discharge phase, the charge phase to another charge phase, the discharge phase to another discharge phase, from the discharge phase to the charge phase or to the other discharge phase and/or from the charge phase to the discharge phase or to the other charge phase.

6. The method according to claim 1, wherein
the reference battery data is data gathered from a historical battery data set of at least one battery batch and/or data from a current battery data set of a same batch.

7. The method according to claim 1, wherein
the quality testing of the battery is performed while the acquiring of the data of the battery is carried out; and/or
the quality testing of the battery is performed on the acquired data according to a fixed step in the battery formation process, during a subsequent step of the battery formation process.

8. The method according to claim 1, wherein
the method further comprises extracting one or more functional profiles from the acquired data; and
the quality testing further comprises comparing the one or more functional profiles of the acquired data and corresponding one or more functional profiles of the reference battery data.

9. The method according to claim 8, wherein
the quality testing further comprises triggering one or more indicators when respective one or more differences between the one or more functional profiles of the acquired data and the corresponding one or more functional profiles of the reference battery data exceed corresponding one or more predetermined thresholds.

10. The method according to claim 8, wherein
the data or the functional profile includes at least one or more of:
derivatives of a charge of the battery with respect to a terminal voltage of the battery per the respective charge and discharge phases and/or derivatives of the terminal voltage of the battery with respect to the charge of the battery per the respective charge and discharge phases;
the charge and/or an energy throughput per the respective charge and discharge phases;
internal resistances per the respective transitional phases;
electrical circuit models per the respective transitional phases and/or the electrical circuit models per the respective charge phases and/or discharge phases; and
coulomb/energy/voltaic efficiencies per the respective cycles.

11. The method according to claim 10, wherein
the quality testing is performed by:
respectively comparing at least one maximum and/or at least one minimum of the derivatives against at least one maximum and/or at least one minimum of derivatives in the reference battery data, and/or respectively comparing the derivatives to corresponding statistical upper and lower boundary curves associated with the derivatives in the reference battery data;
respectively comparing the charge and/or the energy throughput against at least one first statistical boundary condition of the reference battery data;
comparing the internal resistances against at least one second statistical boundary condition of the reference battery data;
fitting parameters of the electrical circuit models to the data or the functional profile and respectively comparing the parameters of the electrical circuit models against corresponding parameters of an equivalent electrical circuit model of the reference battery data and/or respectively comparing the parameters against at least one third statistical boundary condition associated with the corresponding parameters of the reference battery data; and/or
comparing the coulomb and/or energy and/or voltaic efficiencies against at least one fourth statistical boundary condition of the reference battery data, and
wherein the at least one first, second, third and fourth boundary conditions are independent from one another.

12. A computer program, wherein
a computer program product comprises instructions which, when the program is executed by a computer, cause the computer to carry out the steps of the method of claim 1.

13. A computer-readable data carrier, wherein
the computer-readable data carrier has stored there on the computer program of claim 12.

14. A battery formation system for quality testing of a battery, the battery formation system comprising:
a monitor/control unit configured to measure electrical characteristics of the battery and further configured to instruct a battery formation process on the battery;
a processing unit is configured to acquire data of the battery based on the measured electrical characteristics during the battery formation process, wherein the data of the battery temporally relates the measured electrical characteristics of the battery; and
the battery formation system is configured to quality test the battery by phase wise comparing and/or cycle wise comparing the acquired data with reference battery data, and a phase is one of: a charge phase, a transitional phase and a discharge phase of the battery formation process, and a cycle comprises consecutive phases of the charge phase, the transitional phase and the discharge phase.

15. The battery formation system according to claim 14, wherein
the battery formation system is a legacy battery formation system.
